(19) United States
(12) Patent Application Publication
(10) Pub. No.: US 2010/0122721 A1
(43) Pub. Date: May 20, 2010

(54) ARRAY TYPE CONCENTRATING SOLAR CELL SYSTEM

(75) Inventor: Tai Hui LIU, Hsinchu County (TW)

Correspondence Address: HAMRE, SCHUMANN, MUELLER & LARSON, P.C., P.O. BOX 2902, MINNEAPOLIS, MN, 55402-0902, US

(73) Assignee: SOLAPOINT CORPORATION, Hsinchu County (TW)

(21) Appl. No.: 12/273,120

(22) Filed: Nov. 18, 2008

(51) Int. Cl. H01L 31/052; H02N 6/00

(52) U.S. Cl. 136/246

(57) ABSTRACT

An array type concentrating solar cell system without sun-tracing system is provided, wherein a plurality of transparent spheres or sphere-like transparent articles is used as concentrating means and hence there is no need for the concentrating means to trace the light source, such as the Sun. The plurality of transparent spheres (or sphere-like transparent articles), as concentrating means, can provide sufficient electric power for user's applications.

### BACKGROUND OF THE INVENTION

1. Field of the Invention

The present invention is generally related to wide-angle light collecting optical design and alignment to the light source, and more particularly to a transparent sphere as light-collecting device for collecting solar or indoor light to generate power.

2. Description of the Prior Art

Energy generated from solar cell is commonly known as a better and clean energy than other power resources, such as fossil fuel power, nuclear energy power, or hydraulic power. Solar power can be much more superior when the continuing inflation of crude oil. Further, oil is bound to exhaust soon or later, but the solar power, on the other side, is exhaustless power resources compared to petrifaction power. Hence, many governments, research/development units, and private enterprises put numerous research resources into the solar power industry.

For high material cost of photovoltaic cell, and in order to cost down such that the solar power can be commercialized and more popular to staple commodity, now a method is provided to use optical concentrating system to reduce high material cost of using solar cell. The simplest way is to use relative large area of lens to collect lights such that a larger area of lights can be concentrated into a relative smaller area of photovoltaic cell as to increase the power generating efficiency. Nevertheless, due to mass volume and weight of lens, cumbersome solar power generating system is incurred. Furthermore, issues come from conventional lens optical system, such as aberration, chromatic aberration, or focus, can be raised as well. Therefore, some research topics turn to other optical concentrating system to solve the issues above mentioned.

One simple solution is to use Fresnel lens to replace traditional lens. Please refer to FIG. 1, a Fresnel lens 10 focuses lights into a photovoltaic cell 13, wherein thickness of the Fresnel lens 10 can be decreased compared to the traditional lens and larger volume as well as mass of the traditional lens can be reduced significantly. Another solution, provided by Fork and Maeda, uses Cassegrain system as solar collecting system to concentrate lights. The solution they provided can be referred to US Pub. No. 2006/0231133, wherein a primary mirror and a secondary mirror are used to collect lights into photovoltaic cell. Please refer to FIG. 2, a photovoltaic cell 13 is located at the bottom region of a primary mirror 11, and a secondary mirror 12 is located above the primary mirror 11. Lights are irradiated onto the primary mirror 11 and reflected from the secondary mirror 12 into the photovoltaic cell 13.

Two designs of traditional concentrating solar cell module mentioned above have limitation to use high precision solar tracking system, with lens or mirror vertical or perpendicular to incident lights such that solar lights can be concentrated into chip to transform solar lights into electric power. Generally, cost on solar tracking system is about one-fifth of the total cost of all concentrating solar cell module. The more the magnification ratio of the concentrating device is, the more solar tracking precision is, and deviation tolerance decreases. For example, the Earth spins 24 hours a day, and the Sun moves relatively to the Earth at about 15 degree per hour, that is 0.25 degree per minute (unit of time). When magnification ratio of the concentrating device is about 1000, the precision per minute is about 0.9 second.

Therefore, the more magnification ratio of the concentrating device is, the higher precision of the solar-tracking system is. The cost of total concentrating solar cell module will increase significantly and making the concentrating solar cell module not easy to be commercialized.

### SUMMARY OF THE INVENTION

According to the issues raised from the prior art and accommodating to requirement of industrial benefit, this invention provides a simple array type concentrating solar cell system without using a high precision solar tracking system, wherein a plurality of transparent spheres are used as a light-collecting device.

One object of this invention is not to use high cost nor high precision in light-tracking system or solar-tracking system.

Another object of this invention is to provide a simple solar-tracking system in concentrating solar cell module as according to this invention.

### BRIEF DESCRIPTION OF THE DRAWINGS

FIG. 1 illustrates a cross-sectional structure view of a traditional concentrating solar cell system;

FIG. 2 illustrates a cross-sectional structure view of another traditional concentrating solar cell system;

FIG. 3 illustrates a cross-sectional structure view of transparent sphere as concentrating element in concentrating solar cell module in accordance with the present invention;

FIG. 4 illustrates a cross-sectional structure view of two transparent spheres as the concentrating element in accordance with the present invention;

FIG. 5 illustrates a cross-sectional structure view of the concentrating element of FIG. 4 mounting on a solar traceable means in accordance with the present invention;

FIG. 6A and FIG. 6B illustrate cross-sectional structure views of using four transparent spheres as concentrating element in accordance with the present invention;

FIG. 7A and FIG. 7B illustrate another cross-sectional structure views of using four transparent spheres as concentrating element in accordance with the present invention;

FIG. 8 illustrates a cross-sectional structure view of using seven transparent spheres as concentrating element in accordance with the present invention;

FIG. 9A and FIG. 9B illustrate cross-sectional structure views of using multiple photovoltaic cells for the concentrating solar cell module in accordance with the present invention;

FIG. 10 illustrates a cross-sectional structure view of concentrating solar cell mounting on a traceable C-shape arm in accordance with the present invention;

FIG. 11 illustrates a cross-sectional structure view of usable portion of a transparent sphere as concentrating means in accordance with the present invention; and

FIG. 12 illustrates a cross-sectional structure view of removing the peripheral portion around the transparent sphere in accordance with the present invention.

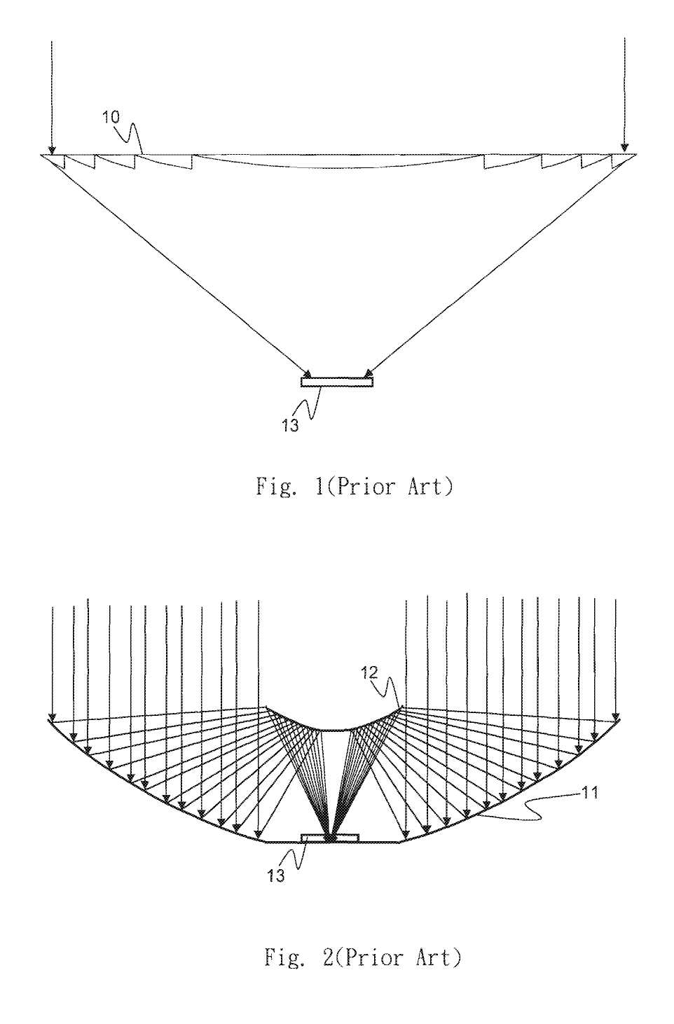

### DESCRIPTION OF THE PREFERRED EMBODIMENTS

What is probed into the invention is a concentrating solar cell module without using high precision solar tracking system. Detailed descriptions of the structure and elements will be provided in the following in order to make the invention thoroughly understood. Obviously, the application of the invention is not confined to specific details familiar to those skilled in the art. On the other hand, the common structures and elements that are known to everyone are not described in details as to avoid unnecessary limitations to the invention.

This invention makes use of a plurality of transparent spheres as a light-collecting element or concentrating element. When the relative position between the light source and the concentrating element is changed, there is no need to move or rotate the concentrating element, and the light can still be focused on the other side of the concentrating element. By using this means, the significance of orientation of light source to the plurality of transparent spheres can be decreased materially. When the light source moves, a plurality of photovoltaic cells can be placed along the moving trace of the light source, or having the photovoltaic cell to track the light source.

The traditional high precision solar-tracking systems cost much higher, and the present invention can reduce the cost significantly by using a more effective and efficient means.

The means of the invention provides an array type concentrating solar cell system, which comprises a concentrating element having a plurality of transparent spheres, and a plurality of photovoltaic cells for receiving lights from the concentrating element and to transfer the received lights into electric power. This invention further comprises a means for tracking the solar track, such that the pluralities of photovoltaic cells can be moved along the path of the solar track.

The concentrating element may comprise two transparent spheres arranged side by side. The array type concentrating solar cell system of this invention comprises an ascension axis penetrating through the diameters of the two transparent spheres, and comprises a C-shape arm attached to the ascension axis, wherein the plurality of photovoltaic cells are located on the C-shape arm.

The concentrating element may comprise four transparent spheres arranged in a square or diagonal shape. Moreover, a central transparent sphere of the concentrating element can be surrounded by six other transparent spheres in a compact arrangement. Each of the plurality of transparent spheres has a plurality of photovoltaic cells allocated in sequence and relatively on the path of the solar track. The array type concentrating solar cell system of this invention further comprises a plurality of C-shape arms each having a transparent sphere placed thereon, wherein that plurality of photovoltaic cells for each transparent sphere are allocated on the corresponding C-shape arm. The array type concentrating solar cell system of this invention may further comprise a plurality of semi-spherical shells each having a transparent sphere placed therein, wherein the plurality of photovoltaic cells for each transparent sphere are allocated on the internal surface of the corresponding semi-spherical shell.

The array type concentrating solar cell system of this invention further comprises a plurality of C-shape arms each having a transparent sphere placed thereon, wherein the plurality of photovoltaic cells for each transparent sphere are allocated on the corresponding C-shape arm. The array type concentrating solar cell system of this invention further comprises a plurality of ascension axes penetrating through the diameter of each of that plurality of transparent spheres, and the two end points of each of the plurality of C-shape arms are attached to the corresponding ascension axis, such that the plurality of photovoltaic cells are encircling the corresponding ascension axis for tracking the solar track.

This invention also provides an array type concentrating solar cell system, which comprises a concentrating element having a plurality of sphere-like transparent articles arranged side by side, and a plurality of photovoltaic cells for receiving lights from the concentrating element and to transfer the light received into electric power. Each of that plurality of sphere-like transparent articles is formed by removing the non-concentrating portion of a transparent sphere. This invention further comprises a means for tracking the solar track, such that the pluralities of photovoltaic cells can be moved along the path of the solar track.

This invention also provides an array type concentrating solar cell system, which comprises a plurality of transparent spheres for concentrating lights which is arranged in an array, and a plurality of photovoltaic cells for receiving lights concentrated from the plurality of transparent spheres and to transfer the lights received into electric power. The array type concentrating solar cell system of this invention further comprises a means for tracking the solar track, such that the plurality of photovoltaic cells can be moved along the path of the solar track.

The material used for the concentrating element can be glass, quartz, plastic, acrylic, PET, PU, mCOC, epoxy, silicone, PMMA, PC, CaF crystal, or MgF crystal. The concentrating element can be manufactured by using inject-molding method. Further, the concentrating element is a hollow spherical shell filled with liquid or solid as to change the refractive index of the transparent sphere.

The following will set forth invention features, detailed explanations and embodiments with illustration of drawings.

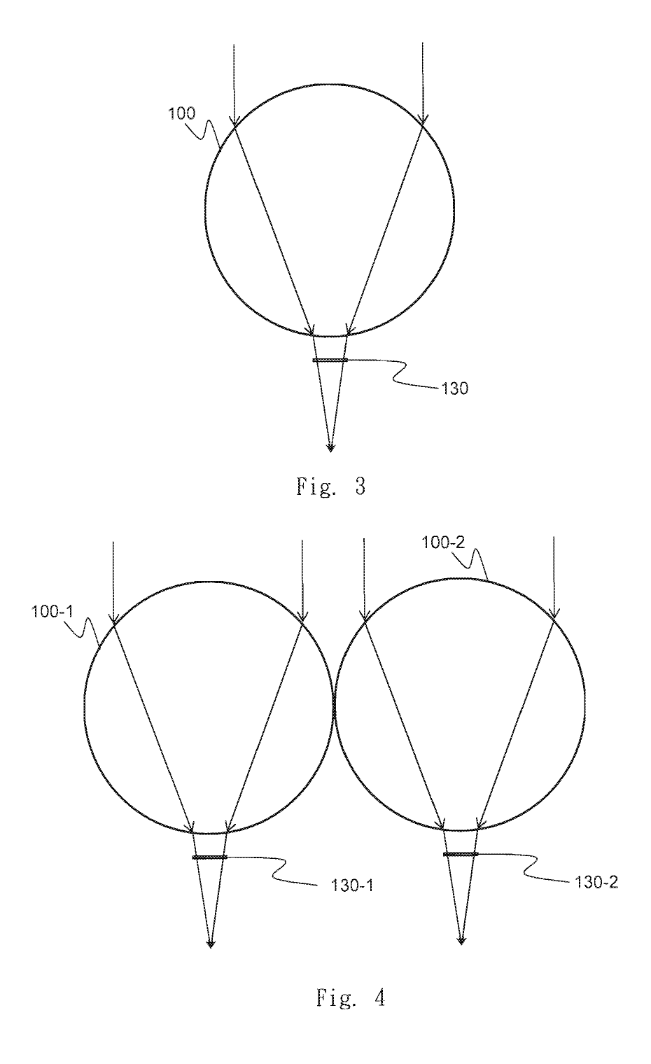

Please refer to FIG. 3, a transparent sphere 100 is used as the concentrating element of the present invention. The material used for the transparent sphere 100 can be glass, quartz, plastic, acrylic, PET, PU, mCOC, epoxy, silicone, PMMA, PC, CaF crystal, or MgF crystal. The transparent sphere 100 can be a hollow spherical shell filled with liquid or solid as to change the refractive index thereof. The transparent sphere 100 can be manufactured by using inject-molding, or grinding.

Due to the transparent sphere 100 is a perfect symmetrical lens, lights from any direction can be focused to a point directly opposite, on the other side of the transparent sphere 100, through the transparent sphere 100. Therefore, there is no need to rotate or move the concentrating element to align with the light source for focusing the light. When in use, a photovoltaic cell 130 is placed at or above the focal point for transforming the collected lights into electric power.

FIG. 4 illustrates a cross-sectional structure view of two transparent spheres as the concentrating element in accordance with the present invention. A first transparent sphere 100-1 and a second transparent sphere 100-2 are arranged side by side or in serial arrangement, wherein a first photovoltaic cell 130-1 and a second photovoltaic cell 130-2 are allocated near the focus of the first transparent sphere 100-1 and the second transparent sphere 100-2 respectively.

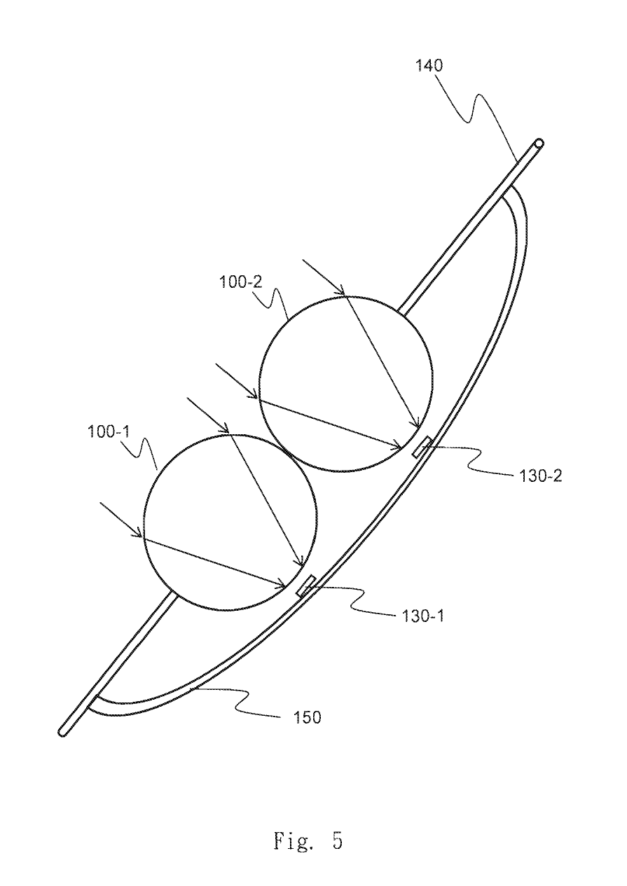

Please refer to FIG. 5, a cross-sectional structure view of the concentrating element as according to FIG. 4 mounting on a solar traceable means in accordance with the present invention is shown. An ascension axis 140, penetrating through both diameters of the first transparent sphere 100-1 and the second transparent sphere 100-2, is attached to the two end points of a C-shape arm 150. The first photovoltaic cell 130-1 and the second photovoltaic cell 130-2 are allocated on the C-shape arm 150, wherein the first photovoltaic cell 130-1 and the second photovoltaic cell 130-2 are allocated near the focus of the first transparent sphere 100-1 and the second transparent sphere 100-2 respectively. The declined angle of the ascension axis 140 is equal to the latitude, such that the ascension axis 140 is parallel to the Earth spin axis. When the Sun moves, the C-shape arm 150 can rotate around the ascension axis 140 and opposite to the movement of the Sun, such that the first photovoltaic cell 130-1 and the second photovoltaic cell 130-2 can be always allocated near the focus of the first transparent sphere 100-1 and the second transparent sphere 100-2 respectively. If tracking accuracy of tracking means constituting of the ascension axis 140 and the C-shape arm 150 should be lowered, more photovoltaic cells 130 can be provided on the solar trace as to compensate the focusing error.

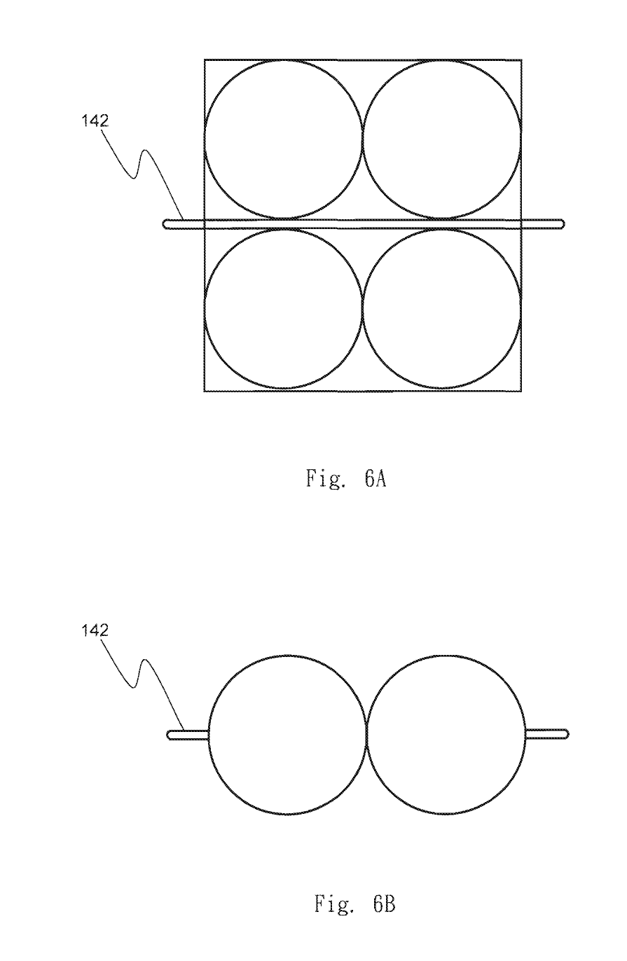

When there are more than two transparent spheres provided, all transparent spheres can be stringed up on the ascension axis. For example, as shown in FIG. 6A and FIG. 6B, provides one embodiment of four transparent spheres, wherein FIG. 6A illustrates a front schematic view from the light source, and FIG. 6B illustrates a side schematic view from light source. Four transparent spheres are arranged in square, and an axis 142 is a central tangent line passing through two nearest neighbor transparent spheres.

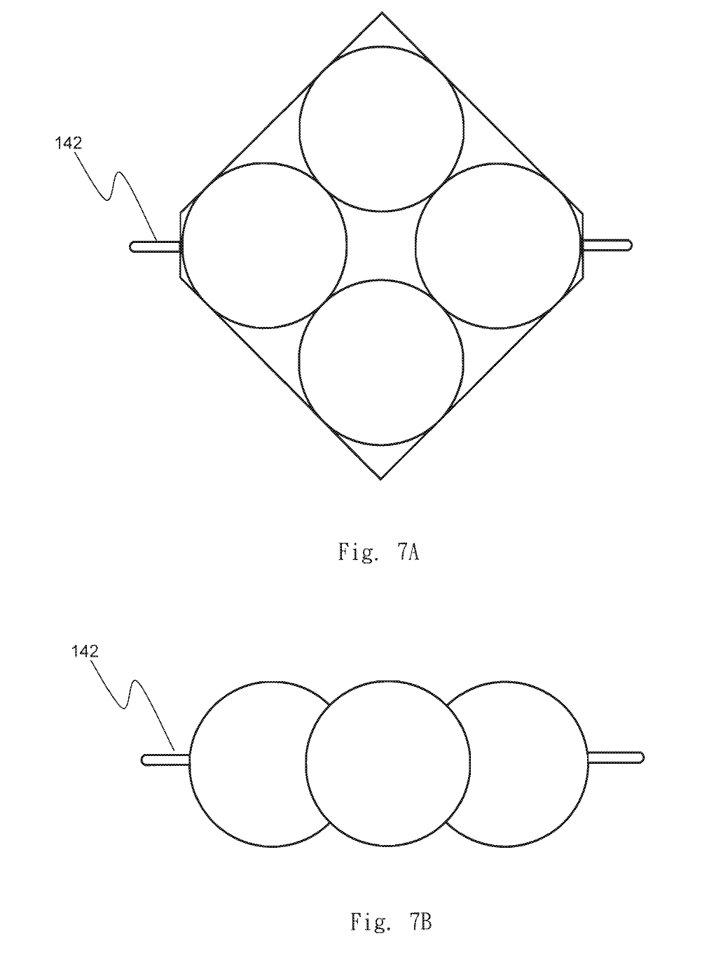

Another means, as shown in FIG. 7A, and FIG. 7B, provides an axis 143 through two diagonal transparent spheres, and the four spheres are arranged in a diagonal shape, wherein FIG. 7A illustrates a front schematic view from the light source, and FIG. 7B illustrates a side schematic view from the light source.

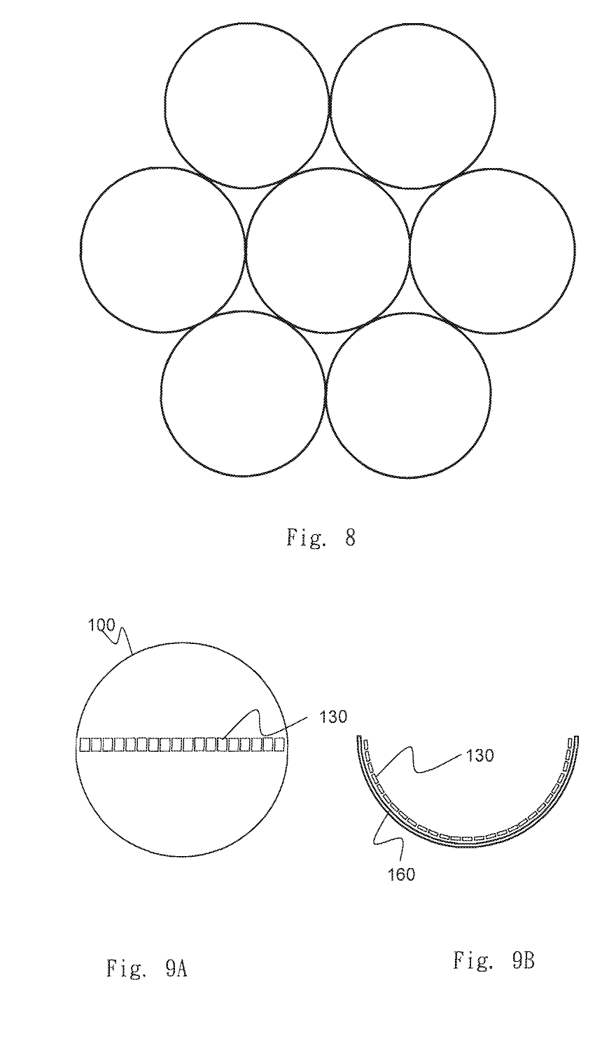

Apart from four transparent spheres, more than four can be provided in this invention. As shown in FIG. 8, one central transparent sphere is surrounded by six transparent spheres in a compact arrangement, when closest arrangement is considered.

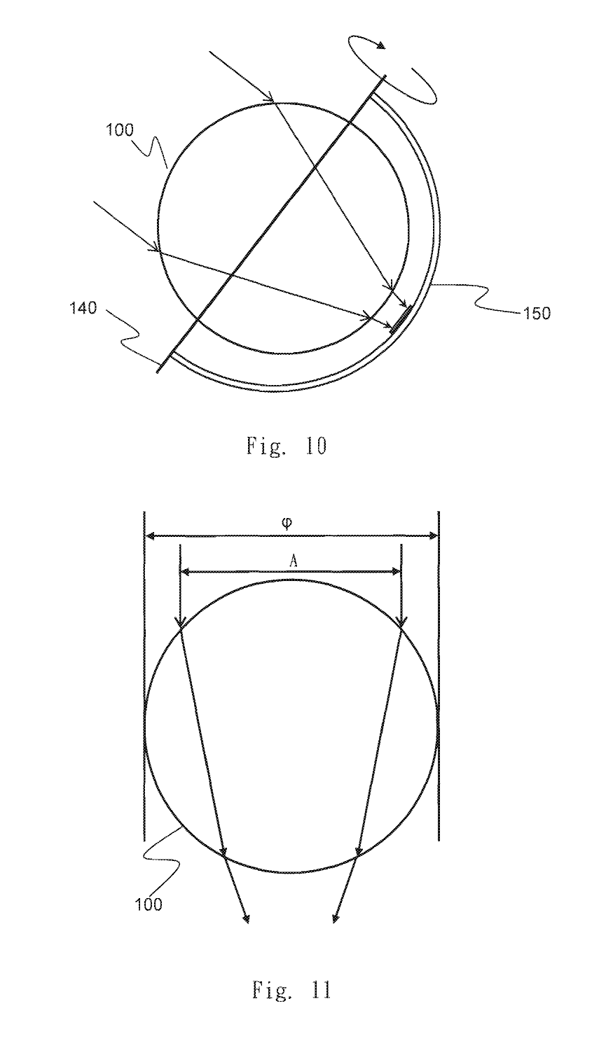

If the Sun has to be traced, a plurality of photovoltaic cells 130 can be placed at the solar track on the transparent sphere 100, as shown in FIGS. 9A and 9B. One embodiment is to use a semi-spherical shell 160 to replace the C-shape arm such that all photovoltaic cells can be located thereon, on the internal surface of the semi-spherical shell, as shown in FIG. 9B. In this embodiment, user can determine the number of photovoltaic cells 130 to be used in accordance with the length of time necessary to generate electric power. For example, if an user determines to generate electric power for only two hours by using solar power, where the Sun will move for about 30 degrees. Therefore, what is needed is to place a plurality of photovoltaic cells 130 in the semi-spherical shell in an amount equal to or more than 30 degrees. There is no tracing means for the entire concentrating system.

When a plurality of transparent spheres is used, a plurality of corresponding semi-spherical shell can be provided to every transparent sphere. This means can apply to embodiments shown in FIG. 6A, FIG. 6B, FIG. 7A, FIG. 7B and FIG. 8. Another way is to provide a single semi-spherical shell to that plurality of transparent spheres, and a plurality of photovoltaic cells is allocated on the paths of each possible movement of the light sources. The former design shall be simple and better.

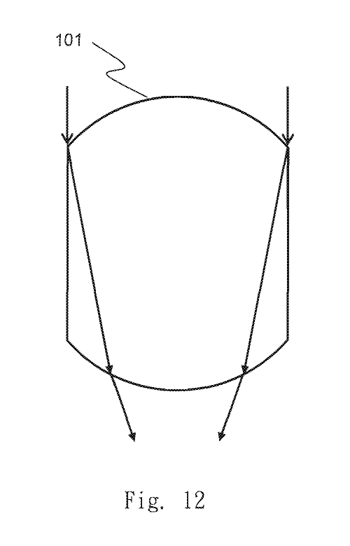

Another means to track solar movement can be referred to FIG. 10. An ascension axis 140 parallel to the Earth spin axis, such that the C-shape arm 150 can rotate around the ascension axis 140 to cancel or offset the Earth spin. The C-shape arm 150 can be replaced by the semi-spherical shell. While the Earth spin is canceled or offset, the Sun can be treated as a still or inactive celestial body. FIG. 10 illustrates a means of single sphere for tracking movement of light source. When such a means is applied to array type transparent spheres, each transparent sphere can be applied tracking means, such that each photovoltaic cell can trace focus of the Sun separately. That is each transparent sphere having an ascension axis penetrating through its diameter, and the two end points of each C-shape arm are attached to the ascension axis, such that each photovoltaic cell can rotate corresponding to the ascension axis to trace solar movement. Moreover, a plurality of semi-spherical shells can be used on each axis of the array, such that photovoltaic cells on each semi-spherical shell can rotate around the ascension axis to trace solar movement. The above mentioned design of the ascension axis can be applied to embodiments of FIG. 6A, FIG. 6B, FIG. 7A, FIG. 7B, and FIG. 8. Not every portion is used to concentrate light in the transparent sphere 100. Please refer to FIG. 11, φ is a diameter of the transparent sphere, and A is the effective length for concentrating light. Therefore, the transparent sphere 100 can be designed to remove the portion of φ—A to form a sphere-like transparent article 101; that is, non-concentrating portion is removed to lower usage of raw material, as shown in FIG. 12. Because FIG. 11 and FIG. 12 are cross-sectional structural views, there can be any possible patterns to that transparent sphere 100 from the view of light source to the non-concentrating portion, i.e., φ—A portion. For example, each of two transparent spheres has one side to remove to bind more closely. When four transparent spheres are provided in this invention, contact portions of the four transparent spheres that are also non-concentrating portions can be removed. When a plurality of transparent spheres is provided and arranged in the most compact way, as shown in FIG. 8, the array of the transparent spheres can be designed like honeycomb pattern; that is, each sphere-like transparent article of concentrating element 101 has six nearest neighbor.

This invention, can be all possible combination and portfolio of above mentioned embodiments, and any combination or portfolio shall be construed as a part of this invention. Every detailed combinations and portfolio do not recite hereinafter.

By using means of this invention, an array type concentrating solar cell system with simple and low cost solar-tracking system can be accomplished, wherein material volume of concentrating element does not have to move or rotate to track light source or the Sun. While light source moves, a plurality of photovoltaic cells can be placed on the predict trace opposite to the light source, such that lights can be irradiated onto the plurality of photovoltaic cells in sequence when light source moves. Another way is to move smaller and lighter photovoltaic cell to track light source; that is, the photovoltaic cell is moved along with the movement of light source. When light source is the Sun, due to the solar track is predictable, a simple tracking mechanism can be designed in this invention. Because of no high precision of solar-tracking system, a concentrating solar cell module with simple and low cost solar-tracking system can be accomplished. Hence, low cost array type concentrating solar cell system can be provided in this invention.

Furthermore, sufficient electric power can be provided in this invention, because a plurality of transparent spheres is used as concentrating element. When array type solar cell system is in series connection, parallel connection or combination thereof, adequate and enough electric power can be provided for user.

Obviously many modifications and variations are possible in light of the above teachings. It is therefore to be understood that within the scope of the appended claims the present invention can be practiced otherwise than as specifically described herein. Although specific embodiments have been illustrated and described herein, it is obvious to those skilled in the art that many modifications of the present invention may be made without departing from what is intended to be limited solely by the appended claims.

What is claimed is:

1. An array type concentrating solar cell system, comprising:
a concentrating element having a plurality of transparent spheres; and
a plurality of photovoltaic cells for receiving lights from said concentrating element and to transfer the lights received into electric power.

2. The array type concentrating solar cell system according to claim 1, wherein said concentrating element comprises two transparent spheres arranged side by side.

3. The array type concentrating solar cell system according to claim 2, further comprising an ascension axis penetrating through the diameters of said two transparent spheres.

4. The array type concentrating solar cell system according to claim 3, further comprising a C-shape arm for placing said two transparent spheres thereon and the two end points of said C-shape arm are attached to said ascension axis, wherein said plurality of photovoltaic cells are located on said C-shape arm.

5. The array type concentrating solar cell system according to claim 1, wherein said concentrating element comprises four transparent spheres arranged in a square or diagonal shape.

6. The array type concentrating solar cell system according to claim 1, wherein a central transparent sphere of said concentrating element is surrounded by six transparent spheres in a compact arrangement.

7. The array type concentrating solar cell system according to claim 1, wherein each of said plurality of transparent spheres has a plurality of photovoltaic cells allocated in sequence and relatively on the path of the solar track.

8. The array type concentrating solar cell system according to claim 7, further comprising a plurality of C-shape arms each having a transparent sphere placed thereon, wherein said plurality of photovoltaic cells for each transparent sphere are allocated on the corresponding C-shape arm.

9. The array type concentrating solar cell system according to claim 7, further comprising a plurality of semi-spherical shells each having a transparent sphere placed therein, wherein said plurality of photovoltaic cells for each transparent sphere are allocated on the internal surface of the corresponding semi-spherical shell.

10. The array type concentrating solar cell system according to claim 1, further comprising a plurality of C-shape arms each having a transparent sphere placed thereon, wherein said plurality of photovoltaic cells for each transparent sphere are allocated on the corresponding C-shape arm.

11. The array type concentrating solar cell system according to claim 10, further comprising a plurality of ascension axes penetrating through the diameter of each of said plurality of transparent spheres, and the two end points of each of said plurality of C-shape arms are attached to the corresponding ascension axis, such that said plurality of photovoltaic cells are encircling the corresponding ascension axis for tracking the solar track.

12. The array type concentrating solar cell system according to claim 1, further comprising means for tracking the solar track, such that said plurality of photovoltaic cells can be moved along the path of the solar track.

13. An array type concentrating solar cell system, comprising:
a concentrating element having a plurality of arranged sphere-like transparent articles arranged side by side; and
a plurality of photovoltaic cells for receiving lights from said concentrating element and to transfer the light received into electric power.

14. The array type concentrating solar cell system according to claim 13, wherein each of said plurality of sphere-like transparent articles is formed by removing the non-concentrating portion of a transparent sphere.

15. The array type concentrating solar cell system according to claim 13, further comprising means for tracking the solar track, such that said plurality of photovoltaic cells can be moved along the path of the solar track.

16. An array type concentrating solar cell system, comprising:
a plurality of transparent spheres for concentrating lights, said plurality of transparent spheres being arranged in an array; and
a plurality of photovoltaic cells for receiving lights concentrated from said plurality of transparent spheres and to transfer the lights received into electric power.

17. The array type concentrating solar cell system according to claim 16, wherein the material of said plurality of transparent spheres is selected from the group consisting of glass, quartz, plastic, acrylic, PMMA, PC, CaF crystal, and MgF crystal.

18. The array type concentrating solar cell system according to claim 17, wherein each of said plurality of transparent spheres is made by using inject-molding.

19. The array type concentrating solar cell system according to claim 16, wherein said each of said plurality of transparent spheres is a hollow spherical shell filled with liquid or solid to change the refractive index of said transparent sphere.

20. The array type concentrating solar cell system according to claim 16, further comprising means for tracking the solar track, such that said plurality of photovoltaic cells can be moved along the path of the solar track.
